(19) United States
(12) Patent Application Publication
(10) Pub. No.: US 2015/0302877 A1
(43) Pub. Date: Oct. 22, 2015

(54) PLASMA POLISH FOR MAGNETIC RECORDING MEDIA

(71) Applicant: HGST Netherlands B.V., Amsterdam (NL)

(72) Inventor: Kai Tang, San Jose, CA (US)

(21) Appl. No.: 14/695,858

(22) Filed: Apr. 24, 2015

Related U.S. Application Data
(63) Continuation-in-part of application No. 13/472,854, filed on May 16, 2012.

(51) Int. Cl. G11B 5/72; H01J 37/32; G11B 5/82

(52) U.S. Cl. CPC G11B 5/72; G11B 5/82; H01J 37/3244

(57) ABSTRACT

Embodiments described herein provide improvements in magnetic recording media by utilizing Xenon plasma to polish a cap layer prior to depositing a carbon overcoat onto the cap layer. One embodiment comprises a method of operating a carbon overcoat deposition station. The method comprises inserting a magnetic recording disk into the deposition station that includes a cap layer that is exchange coupled to a magnetic recording layer. The method further comprises supplying a source of Xenon gas to the deposition station, and applying a negative bias voltage to the cap layer. The method further comprises ionizing the Xenon gas in the deposition station to generate Xenon plasma, and to polish the cap layer utilizing the Xenon plasma to a roughness of 5 angstroms or less.

### RELATED APPLICATIONS

This patent application is a continuation-in-part of co-pending U.S. non-provisional patent application Ser. No. 13/472,854, filed on 16 May 2012 and entitled “PLASMA POLISH FOR MAGNETIC RECORDING MEDIA”, which is incorporated by reference.

### FIELD

The disclosure is related to the field of magnetic recording media.

### BACKGROUND

One type of recording media that is used in modern disk drive systems is perpendicular magnetic recording (PMR) media. PMR media includes a magnetic recording layer that has an easy axis of magnetization oriented substantially perpendicular to the substrate. Hexagonal Close Packed (HCP) Co-alloys are typically used as the magnetic recording layer for perpendicular recording. The easy axis of magnetization for these materials lies along the c-axis or <0001> direction.

PMR media is generally formed on a substrate with a soft magnetic underlayer (SUL), one or more interlayers, and a perpendicular magnetic recording layer. The soft magnetic underlayer (SUL) serves to concentrate a magnetic flux emitted from a main pole of a write head and to serve as a flux return path back to a return pole of the write head during recording on the magnetic recording layer. The interlayers (also referred to as seed layers) serve to control the size of magnetic crystal grains and the orientation of the magnetic crystal grains in the magnetic recording layer. The interlayers also serve to magnetically de-couple the SUL and the magnetic recording layer. The magnetic recording layer is the layer in which bit data is stored based on the orientation of the magnetization of individual magnetic grains.

Because the magnetic recording layer has a magnetization that is oriented parallel to magnetic fields used to write to the media, reversing the magnetization of the magnetic recording layer may be difficult. To assist in reversing the magnetization of the magnetic grains in the magnetic recording layer, PMR media may also include a cap layer that is exchange coupled to the magnetic recording layer. The cap layer is typically formed from a CoPt alloy, such as CoPt, CoPtCr, CoPtCrB, etc. The cap layer may directly contact the magnetic recording layer, or a coupling layer may be fabricated between the cap layer and the magnetic recording layer. When a coupling layer is used, the structure is sometimes referred to as an exchange spring structure.

As the areal bit density of a magnetic recording media increases, the magnetic regions in the recording layer that encode bit data become smaller. This may reduce the read signal generated in a read head of the disk drive system. One solution to improve the read signal is to reduce a thickness of the carbon overcoat that is typically applied to the cap layer. The carbon overcoat is a non-magnetic layer applied to the cap layer to protect the media from corrosion and/or damage. Thus, reducing the carbon overcoat thickness potentially reduces the relative distance between the read head and the cap layer. However, as the carbon overcoat becomes thinner, the corrosion resistance of the disk may degrade, especially if the overcoat is rough.

Another solution for improving the read signal is to reduce the clearance between the read head and the top surface of the disk. However, one consequence of a reduced clearance is head-to-disk contact, which is undesirable. Head-to-disk contact occurs when a slider that includes the read head makes contact with the disk. Head-to-disk contact may cause damage to the slider, the disk, or both. It therefore remains an ongoing challenge to improve the performance of magnetic media.

### SUMMARY

Embodiments described herein provide improvements in magnetic recording media by utilizing Xenon plasma to polish the cap layer prior to depositing a carbon overcoat onto the cap layer. Polishing the cap layer reduces a roughness of the top surface of the cap layer, and therefore, the resulting roughness of the carbon overcoat that is formed on the cap layer is reduced. A smoother carbon overcoat on the disk improves the clearance between the slider and the disk. Also, a smoother carbon overcoat on the disk improves the corrosion resistance of the disk, and the carbon overcoat may be made thinner without sacrificing the corrosion resistance of the disk. A thinner carbon overcoat reduces the relative distance between the read head and the cap layer.

One embodiment comprises a method of operating a carbon overcoat deposition station. The method comprises inserting a magnetic recording disk into the deposition station that includes a cap layer that is exchange coupled to a magnetic recording layer. The method further comprises supplying a source of Xenon gas to the deposition station, and applying a negative bias voltage to the cap layer. The method further comprises ionizing the Xenon gas in the deposition station to generate Xenon plasma, and to polish the cap layer utilizing the Xenon plasma to a roughness of 5 angstroms or less.

Another embodiment comprises a method of operating a carbon overcoat deposition station. The method comprises inserting a magnetic recording disk into the deposition station that includes a cap layer that is exchange coupled to a magnetic recording layer. The method further comprises supplying a source of Xenon gas to the deposition station, and applying a negative bias voltage to the cap layer. The method further comprises ionizing the Xenon gas in the deposition station to generate Xenon plasma, and to polish the cap layer utilizing the Xenon plasma. The method further comprises terminating the source of Xenon gas to the deposition station, and supplying a source of carbon carrying gas to the deposition station. The method further comprises depositing a carbon overcoat on the polished cap layer.

Another embodiment comprises a magnetic recording disk. The magnetic recording disk includes a magnetic recording layer that is configured to store bit data for the magnetic recording disk. The magnetic recording disk further includes a cap layer that is polished utilizing Xenon plasma to a roughness of 5 angstroms or less, where the cap layer is formed on and is exchanged coupled with the magnetic recording layer. The magnetic recording disk further includes a carbon overcoat that is formed on the cap layer.

The above summary provides a basic understanding of some aspects of the specification. This summary is not an extensive overview of the specification. It is intended to neither identify key or critical elements of the specification nor delineate any scope particular embodiments of the specification, or any scope of the claims. Its sole purpose is to present some concepts of the specification in a simplified form as a prelude to the more detailed description that is presented later.

### DESCRIPTION OF THE DRAWINGS

Some embodiments of the present invention are now described, by way of example only, and with reference to the accompanying drawings. The same reference number represents the same element or the same type of element on all drawings.

FIG. 1 is a flow chart illustrating a method of fabricating a magnetic recording disk in an exemplary embodiment.

FIG. 2 is a cross-sectional view illustrating a portion of a disk after depositing a film in an exemplary embodiment.

FIG. 3 is a cross-sectional view illustrating a portion of a disk after polishing a top surface of a film in an exemplary embodiment.

FIG. 4 is a cross-sectional view illustrating the disk after depositing a subsequent layer on a polished top surface of a film in an exemplary embodiment.

FIG. 5 is a flow chart illustrating another method of fabricating a magnetic recording disk in an exemplary embodiment.

FIG. 6 is a cross-sectional view illustrating a portion of a disk after depositing a magnetic recording layer in an exemplary embodiment.

FIG. 7 is a graph illustrating a magnetic layer thickness vs. Argon flow rate at various bias voltages as determined during testing.

FIG. 8 is a cross-sectional view illustrating a portion of a disk after polishing a top surface of a recording layer in an exemplary embodiment.

FIG. 9 is a cross-sectional view illustrating a portion of a disk after depositing carbon overcoat on a polished top surface of a recording layer in an exemplary embodiment.

FIG. 10 is a cross-sectional view illustrating a portion of a disk after depositing a cap layer onto a magnetic recording layer in an exemplary embodiment.

FIG. 11 is a flow chart illustrating a method of operating a deposition station for plasma polishing a magnetic recording disk in an exemplary embodiment.

FIG. 12 is a cross-sectional view illustrating a disk after polishing a top surface of a cap layer in an exemplary embodiment.

FIG. 13 is a cross-sectional view illustrating a disk after depositing a carbon overcoat onto a top surface of a cap layer in an exemplary embodiment.

FIG. 14 is a graph illustrating variations in an interfacial roughness between a carbon overcoat and a cap layer at different Xenon polishing and Argon polishing flow rates as determined during testing.

FIG. 15 is a graph illustrating variations in an interfacial roughness between a carbon overcoat and a cap layer using Xenon polishing at different bias voltages as determined during testing.

### DESCRIPTION OF EMBODIMENTS

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention, and are to be construed as being without limitation to such specifically recited examples and conditions. As a result, the invention is not limited to the specific embodiments or examples described below, but by the claims and their equivalents.

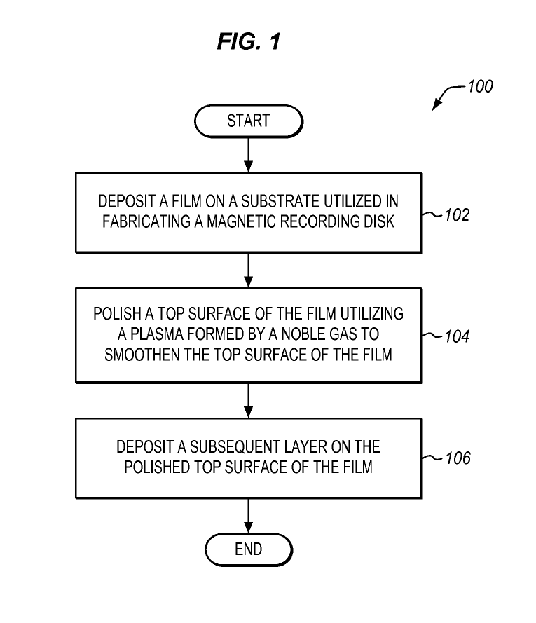

FIG. 1 is a flow chart illustrating a method 100 of fabricating a magnetic recording disk in an exemplary embodiment. Method 100 may be performed in one or more fabrication modules that are used to fabricate magnetic recording disks. For example, method 100 may be performed in a Direct Current (DC) magnetron sputter deposition station and/or a New Carbon Technology (NCT) station. The steps of the flowcharts provided herein are not all inclusive and other steps, not shown, may be included. Further, the steps may be performed in an alternative order.

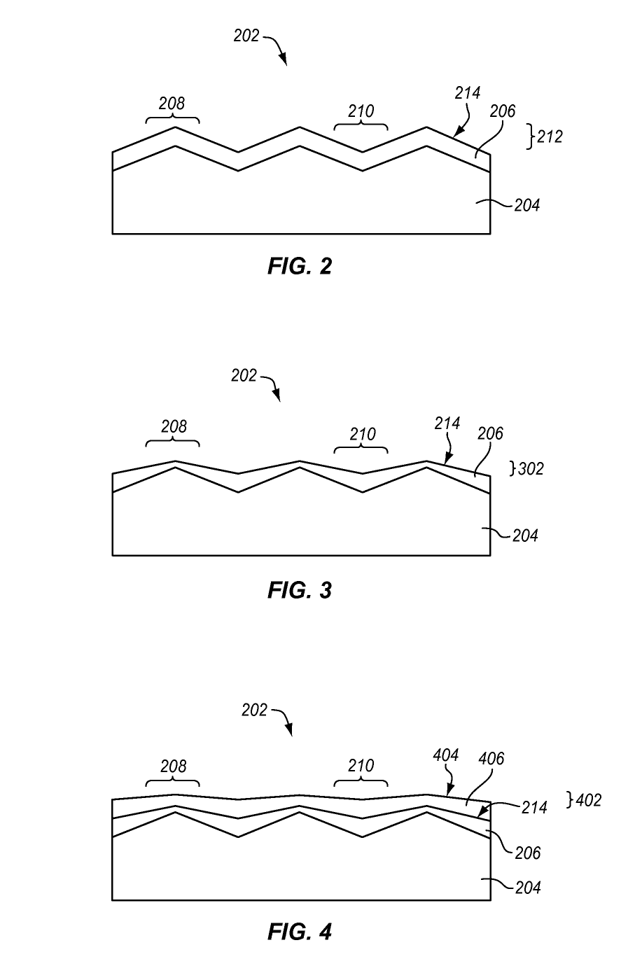

Step 102 comprises depositing a film of a magnetic recording disk. Although not shown, the film may be deposited on a substrate or on another film of the disk that was previously deposited. Some examples of the film are a soft magnetic underlayer (SUL), a magnetic underlayer, a non-magnetic underlayer, a magnetic recording sublayer, a magnetic recording layer, a magnetic cap layer, etc. FIG. 2 is a cross-sectional view illustrating a portion of a disk 202 after depositing a film 206 onto a substrate 204 in an exemplary embodiment. The portion of disk 202 illustrated in FIG. 2 and the other figures is a magnified view to show the roughness of the surface of films. As shown in FIG. 2, the top surface 214 of film 206 is relatively rough after the deposition step. Top surface 214 has a number of peaks 208 and valleys 210 that modulate a height 212 of top surface 214. During the fabrication process for disk 202, subsequent layer(s) that are deposited onto film 206 will inherit some or all of the roughness of film 206 during the deposition process, and therefore will also not be particularly smooth. This may be problematic for a number of reasons. First, it is desirable to make the top surface of disk 202 as smooth as possible. A smooth top surface on disk 202 improves the clearance between a read/write head (not shown in the figures) and the magnetic recording disk, which allows the read/write head to fly closer to disk 202. Another reason to make the top surface of disk 202 as smooth as possible is related to the corrosion resistance of disk 202. Rough surfaces tend to corrode faster than smooth surfaces because of an increase in the amount of surface area that a rough surface presents to an environment.

In order to achieve some measure of corrosion resistance, disk fabricators desire smoother surfaces, or fabricate thicker protective layers in order to reduce the corrosion rate of the recording media. However, thick protective layers are typically non-magnetic carbon-like layers (Diamond-Like Carbon (DLC), carbon overcoats, etc.) that act to separate the read/write head from the magnetic recording layer used to store bit data on the disk. As this separation increases, which is also referred to as the magnetic spacing, the read signal (for a constant magnetic region size) decreases. This is undesirable and problematic because as the bit density of magnetic recording media increases, the number of magnetic grains (and therefore the size of the magnetic regions used to store data) decreases.

Step 104 (see FIG. 1) comprises polishing a top surface of a film using a plasma formed by a noble gas. FIG. 3 is a cross-sectional view illustrating a portion of disk 202 after polishing top surface 214 of film 206 in an exemplary embodiment. FIG. 3 illustrates how the roughness of top surface 214 is reduced as compared to the roughness of top surface 214 illustrated in FIG. 2 after the film 206 was first deposited. During the polishing process, plasma is formed proximate to film 206 from one or more noble gases, such as Argon, Krypton, Neon, Xenon, etc. The atoms of the noble gas, now ionized, accelerate toward disk 202 and knock atoms from film 206 loose. This tends to reduce the roughness of top surface 214 by decreasing/reducing irregularities or unevenness of top surface 214, as illustrated by height 302, which is now less than height 212 of FIG. 2.

Step 106 comprises depositing a subsequent layer on the polished top surface of a film. FIG. 4 is a cross-sectional view illustrating disk 202 after depositing subsequent layer 406 on a polished top surface 214 of film 206 in an exemplary embodiment. After depositing layer 406, top surface 214 becomes an interfacial layer between layer 406 and film 206. During the deposition process, layer 406 grows on top of film 206 and therefore, has a smoother surface (e.g., illustrated by height 402) to form on due to the plasma polishing process applied to film 206. As a result, top surface 404 of layer 406 is likewise smoother. Because top surface 404 of layer 406 is smoother, the corrosion resistance of layer 406 increases. Also, subsequent layers deposited on layer 406 will grow on a smoother surface, and therefore may inherit this smoothness for surface(s) grown on layer 406.

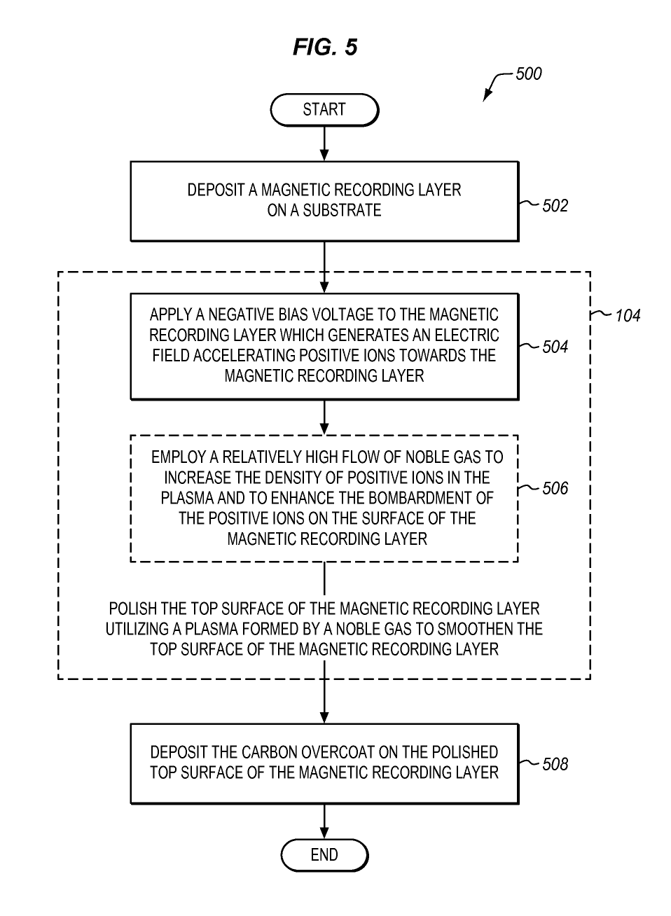

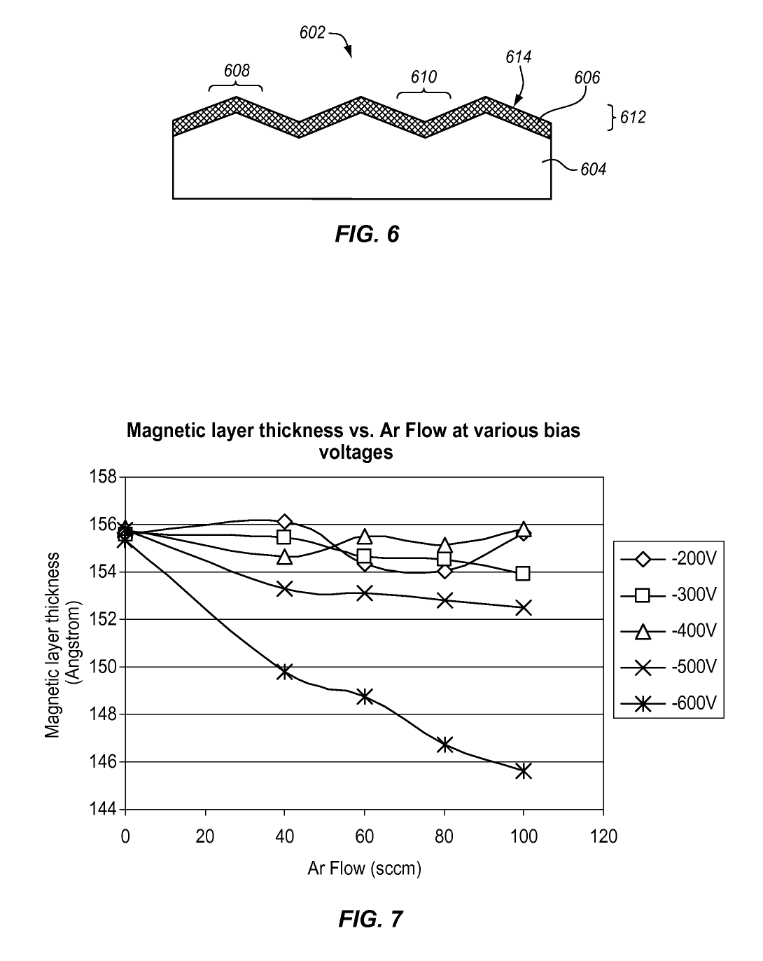

FIG. 5 is a flow chart illustrating another method of fabricating a magnetic recording disk in an exemplary embodiment. Step 502 comprises depositing a magnetic recording layer utilized to fabricate a magnetic recording disk. FIG. 6 is a cross-sectional view illustrating a portion of a disk 602 after depositing a magnetic recording layer 606 onto a substrate 604 in an exemplary embodiment. Typically, recording layer 606 is a stack of multiple magnetic films that form magnetic regions for storing bits of data. As shown in FIG. 6, top surface 614 of recording layer 606 is not smooth after being deposited. Top surface 614 has a number of peaks 608 and valleys 610 that modulate a height 612 of top surface 614. In order to protect recording layer 606 from corrosion and damage, a carbon overcoat is applied to recording layer 606. With a rough magnetic recording layer 606, depositing a carbon overcoat on recording layer 606 results in rough carbon overcoat for disk 602.

Steps 504 and 506 are utilized in performing a polishing process on the top surface of a magnetic recording layer using plasma. Step 504 and 506 are additional exemplary details of the polishing process described previously for step 104 of method 100 (see FIG. 1). During the polishing process, noble gas atoms (e.g., Krypton, Argon, Neon, Xenon, etc.) bombard the surface of the magnetic recording layer and knock material off of the magnetic recording layer. More particularly, atoms near peaks are more exposed and available for polishing. Step 504 comprises applying a negative bias voltage to the magnetic recording layer, which generates an electric field and accelerates positive ions toward the magnetic recording layer. For example, disk 602 may be inserted into a DC magnetron sputtering station, and a DC voltage of between about−400 and −600 volts is applied to recording layer 606 relative to a sputter shield. Step 506 is an optional step for method 500. Step 506 comprises employing a relatively high flow of noble gas to increase the density of the positive ions in the plasma. The increase in density also enhances the bombardment of the positive ions on the surface of the magnetic recording layer. In some embodiments, the flow rate of the noble gas is above about forty Standard Cubic Centimeters per Minute (SCCM). FIG. 7 is a graph illustrating a magnetic layer thickness vs. Argon flow rate at various bias voltages as determined during testing.

FIG. 7 illustrates that the magnetic layer thickness is substantially unchanged at bias voltages between −500 V and −200 V regardless of the Argon flow rate. However, when the bias voltage of about −600V is applied, there is a strong flow-dependent reduction of the magnetic layer thickness, thus allowing fabricators to control the polishing rate of a magnetic layer by varying the Argon flow rate at a −600V bias voltage. The optimum negative bias can be selected based on how much film needs to be removed to reach the desired smoothness and the specific geometry of the sputtering station used for the polish process. It can be a negative bias with absolute value greater than 600V as well. The sputtering targets used in the DC magnetron station for the polish process can have elements such as Co, Pt, Cr, B, Ta, Ru, C, and any combination of these elements. Some examples of the target compositions are CoPtCrB, Cr, CrB, Ta, Ru, C. In addition to the noble gas, C₂H₂, C₂H₄, H₂, 0₂, and N₂ may be injected to the station during the polish process also.

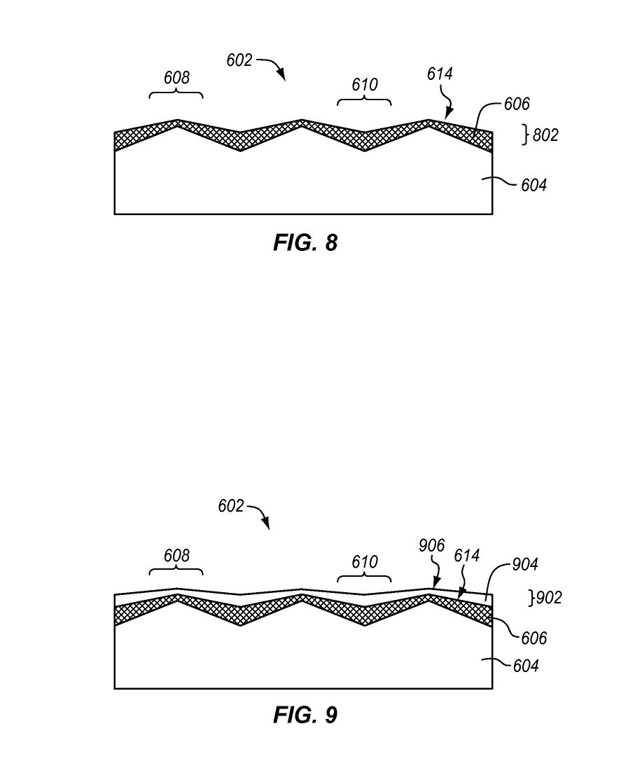

FIG. 8 is a cross-sectional view illustrating a portion of disk 602 after polishing top surface 614 of recording layer 606 in an exemplary embodiment. Step 508 of FIG. 5 comprises depositing a carbon overcoat on the polished top surface of a recording layer. FIG. 9 is a cross-sectional view illustrating a portion of disk 602 after depositing a carbon overcoat 904 on the polished top surface 614 of recording layer 606 in an exemplary embodiment. After depositing carbon overcoat 904, top surface 614 of recording layer 606 becomes an interfacial layer between carbon overcoat 904 and recording layer 606. During the deposition process, carbon overcoat 904 grows on top of recording layer 606, and therefore has a smoother surface to form on due to the plasma polishing process. Therefore, top surface 906 of carbon overcoat 904 is likewise smoother. A smooth carbon overcoat 904 improves the clearance between a read/write head (not shown) and top surface 906, and improves the read signal generated in the head by disk 602.

During clearance testing, the inventors found that plasma polishing the media resulted in a clearance improvement from 8 nanometers to 8.5 nanometers over standard fabrication processes that did not include plasma polishing. The inventors further found that that standard fabrication processes for a magnetic disk (i.e., that did not use the plasma polishing process described herein) resulted in a carbon overcoat surface roughness of about 6.9 angstroms and a magnetic layer/carbon interfacial roughness of about 8 angstroms. The surface roughness and interfacial roughness were determined by X-ray reflectivity. Similar tests were performed on media that was plasma polished. Both the carbon overcoat surface roughness and the magnetic layer/carbon interfacial roughness were about 5.1 angstroms, which are less than what were found for the standard fabrication process. A smoother carbon overcoat 904 allows fabricators to make carbon overcoat 904 thinner, because the corrosion resistance of disk 602 is improved. When carbon overcoat 904 is thinner, the magnetic spacing between the read/write head and recording layer 606 is reduced. The reduction in the magnetic spacing allows for improved read/write performance when disk 602 is part of a disk drive system. During testing, the inventors found that standard fabrication processes for a magnetic disk (i.e., that did not use the plasma polishing process described herein) resulted in a corrosion product for a 28 angstrom thick carbon overcoat of about 3.6 nanograms. The amount of the corrosion product was determined by measuring a Co (cobalt) extraction count. Similar tests were performed on media that was plasma polished. A plasma polished 28 angstrom overcoat sample resulted in a 0.5 nanogram Co extraction count, which is significantly improved over the standard fabrication process. A 22 angstrom thick overcoat was also fabricated with the plasma polish process. Testing revealed that the Co extraction count for the sample was 0.8 nanograms. Therefore, even though the carbon overcoat in the 22 angstrom sample was thinner, plasma polishing of the media resulted in a corrosion resistance improvement from 3.6 nanograms to 0.8 nanograms over the standard fabrication process.

In another embodiment, Xenon can be used as a polishing ion for the plasma polishing process rather than Argon. In plasma polishing, ionized gas atoms (e.g., Xenon and/or Argon) are accelerated towards a layer on the disk that has already been deposited. For example, plasma polishing may be performed on a cap layer prior to depositing a carbon overcoat on the cap layer. The polishing ions collide with the top surface of the cap layer, transfer momentum and energy to the atoms of the cap layer, and remove them away from the top surface of the cap layer.

The energy transfer between the polishing ions and the atoms in the top surface of the magnetic recording layer is most efficient when they have the same mass. In PMR media and in Shingle Magnetic Recording (SMR) media, the top magnetic layer is referred to as a cap layer, which is exchange coupled to an underlying magnetic recording layer. Cap layers typically comprise Platinum (Pt), Cobalt (Co), Chromium (Cr), and/or Boron (B) along with possible oxides of these elements. Table 1 below lists the atomic number of the cap layer elements along with possible polishing ions that may be used in a plasma polishing process of the cap layer.

TABLE 1
cap layer and polishing ion masses

| Cap Layer element | Polishing Ion | Atomic Number |
|---|---|---|
| Boron | | 5 |
| Oxygen | | 8 |
| | Argon | 18 |
| Chromium | | 24 |
| Cobalt | | 27 |
| | Krypton | 36 |
| | Xenon | 54 |
| Platinum | | 78 |
| | Radon | 86 |

Based on the atomic number, the removal of Platinum atoms would be more efficient when using Xenon as the polishing ion rather than Argon as the polishing ion because the atomic number of Xenon (54) is closer to that of Platinum (78) than that of Argon (18). Although the atomic number of Radon (86) is closer still, Radon is radioactive and may not be practical for use in a manufacturing environment.

In the embodiments described below, a carbon overcoat deposition station is used to plasma polish the cap layer using Xenon prior to depositing the carbon overcoat onto the cap layer. One example of a carbon overcoat deposition station is a New Carbon

Technology (NCT) station. NCT stations are manufactured by Intevac. NCT stations are designed for deposition of ultra-thin, high-density carbon overcoats onto magnetic media, such as disks. Carbon overcoats may also be referred to as DLC overcoats or DLC layers. To deposit a carbon overcoat using an NCT station, a filament is heated to a high temperature to emit electrons. These electrons ionize gas molecules or atoms to form a plasma. Gases that comprise Carbon and Hydrogen elements are supplied to the NCT station, which decompose into Carbon and Hydrogen ions and atoms. A carbon overcoat is then grown by the deposition of Carbon ions and atoms onto the cap layer of the disk.

For plasma polishing in a NCT station, a disk is inserted into the NCT station that includes a cap layer deposited onto a magnetic recording layer, and Xenon is supplied to the NCT station rather than the gases used to form a carbon overcoat on the disk (e.g., gases that comprise Carbon and Hydrogen elements).

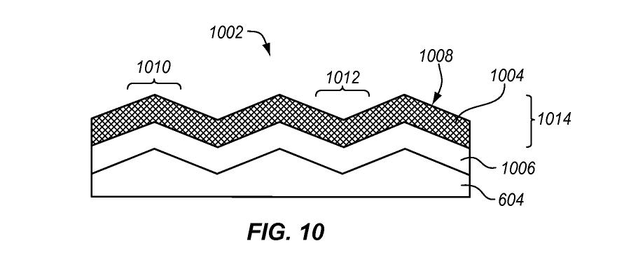

FIG. 10 is a cross-sectional view illustrating a portion of a disk 1002 after depositing a cap layer 1004 onto a magnetic recording layer 1006 in an exemplary embodiment. Typically, recording layer 1006 is a stack of multiple magnetic films that form magnetic regions for storing bits of data, and cap layer 1004 is exchange coupled to magnetic recording layer 1006 to assist in reversing the magnetization of the magnetic grains in magnetic recording layer 1006. Although FIG. 10 illustrates that cap layer 1004 is in contact with magnetic recording layer 1006, a coupling layer may be fabricated between cap layer 1004 and magnetic recording layer 1006. When a coupling layer is used, the combination of cap layer 1004 and the coupling layer may be referred to as an exchange spring structure.

As shown in FIG. 10, a top surface 1008 of cap layer 1004 is not smooth after being deposited. Top surface 1008 has a number of peaks 1010 and valleys 1012 that modulate a height 1014 of top surface 1008. In order to protect disk 1002 from corrosion and damage, a carbon overcoat is applied to cap layer 1004. With a rough cap layer 1004, depositing a carbon overcoat on cap layer 1004 results in rough carbon overcoat for disk 1002. This is undesirable for a number of reasons previously discussed.

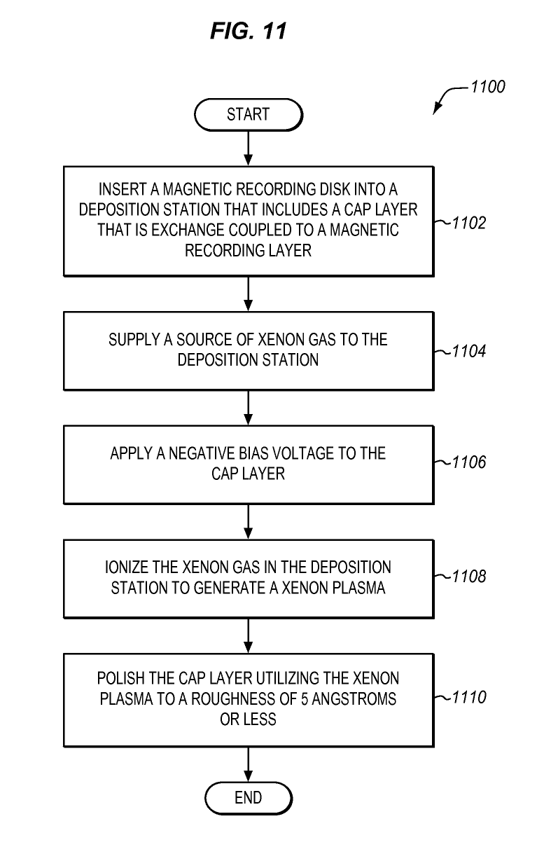

FIG. 11 is a flow chart illustrating a method 1100 of operating a carbon overcoat deposition station for plasma polishing a magnetic recording disk in an exemplary embodiment. To plasma polish cap layer 1004 of disk 1002, disk 1002 is inserted into the deposition station (see step 1102 of method 1100). Xenon gas is supplied to the deposition station instead of the typical Carbon and Hydrogen based gasses that are supplied for depositing the carbon overcoat (see step 1104). A negative bias voltage is applied to cap layer 1004 (see step 1106).

The filament in the deposition station (e.g., a NCT station) is heated to a high temperature to emit electrons. These electrons ionize the Xenon gas to generate Xenon plasma (see step 1108). The negative bias voltage applied to cap layer 1004 accelerates the positive Xenon ions toward cap layer 1004, plasma polishing top surface 1008 of cap layer 1004 to generate a smooth surface. Top surface 1008 of cap layer 1004 may be polished to roughness of 5 angstroms or less (see step 1110). Polishing top surface 1008 of cap layer 1004 allows for a subsequent layer (e.g., a carbon overcoat) to be grown on a smoother surface than would be possible without plasma polishing cap layer 1004. Since the subsequent layer grows on a smoother surface, a top surface of the subsequent layer will have a smoother surface.

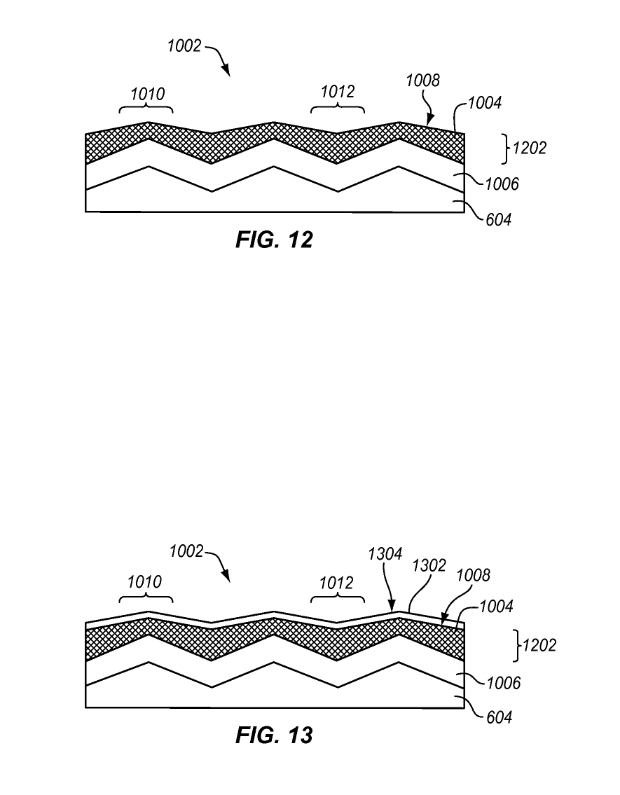

FIG. 12 is a cross-sectional view illustrating disk 1002 after polishing top surface 1008 of cap layer 1004 in an exemplary embodiment. As shown in FIG. 12, top surface 1008 of cap layer 1004 is smooth after being plasma polished in the deposition station. Top surface 1008 has a number of peaks 1010 and valleys 1012 that modulate a height 1202 of top surface 1008. In response to plasma polishing cap layer 1004, height 1202 of top surface 1008 in FIG. 12 is less than height 1014 in FIG. 10.

Carbon and Hydrogen based gasses may then be supplied to the deposition station (e.g., a NCT station) rather than Xenon in order to deposit the carbon overcoat onto the smoothened top surface 1008 of cap layer 1004. Plasma polishing of cap layer 1004 and the deposition of the carbon overcoat onto cap layer 1004 can be performed in the deposition station without removing disk 1002 from the deposition station. In other embodiments, the deposition of the carbon overcoat onto cap layer 1004 can be performed in a different deposition station (e.g., a NCT station) after cap layer 1004 is polished.

FIG. 13 is a cross-sectional view illustrating disk 1002 after depositing a carbon overcoat 1302 on top surface 1008 of cap layer 1004 in an exemplary embodiment. During the deposition process, carbon overcoat 1302 grows on top of cap layer 1004, and has a smoother surface to form on due to the plasma polishing process. Therefore, top surface 1304 of carbon overcoat 1302 is likewise smoother. A smooth carbon overcoat 1302 improves the clearance between a read/write head (not shown) and top surface 1304 of carbon overcoat 1302, which improves the read/write performance of disk 1002. After depositing carbon overcoat 1302, top surface 1008 of cap layer 1004 becomes an interfacial layer between carbon overcoat 1302 and cap layer 1004.

During testing of Xenon as a polishing ion for reducing the roughness of cap layers prior to the deposition of a carbon overcoat, it was found that Xenon provided a lower roughness than Argon at the interface between the cap layers and the carbon overcoats.

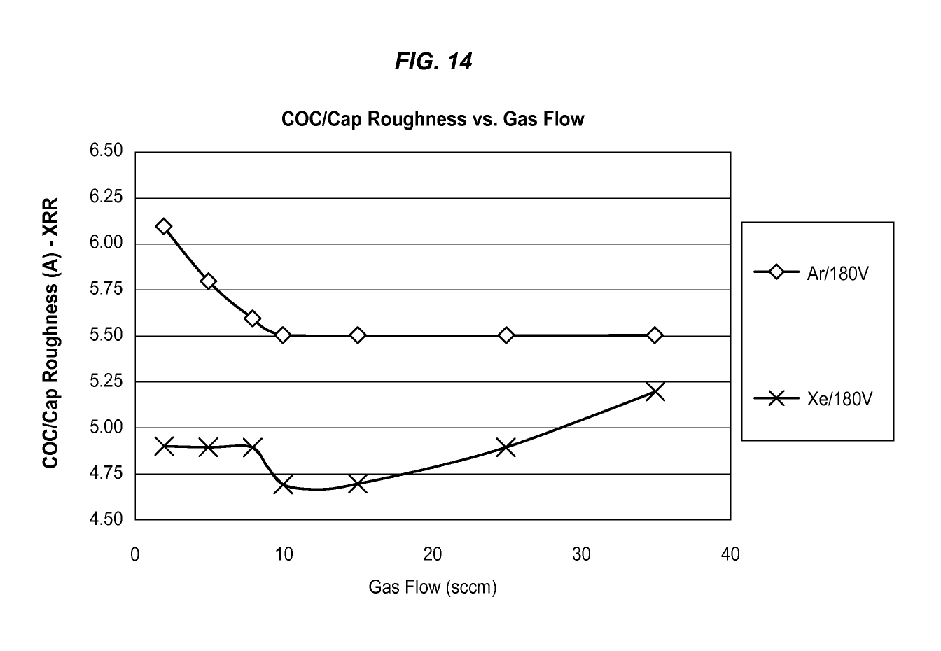

FIG. 14 is a graph illustrating variations in an interfacial roughness between a carbon overcoat (COC) and a cap layer at different Xenon and Argon flow rates as determined during testing. The results plotted for FIG. 14 were obtained by X-ray reflectivity (XRR) analysis using a NCT station and a bias of −180V. One benefit of using a NCT station to perform the plasma polishing process is that a NCT station does not have a sputtering target, while a DC magnetron station does have a sputtering target.

In some cases, the use of a sputtering target during the plasma polishing process may introduce contamination onto the cap layer from the sputtering target. Further, the bias voltages in a NCT station are lower (−180V) as compared to a DC magnetron sputter station (−600V) which can be desirable for reducing the possibility of arcing and/or localized heating of the disk where electrical connections are made to the disk.

FIG. 14 illustrates that the interfacial roughness between the carbon overcoat and the cap layer using Argon polishing was determined to be about 5.5 angstroms at about 10 SCCM, while the interfacial roughness using Xenon polishing was determined to be about 4.7 angstroms at about 10 SCCM. The use of Xenon as the polishing ion in an NCT station reduces the interfacial roughness between the carbon overcoat and the cap layer as compared to Argon polishing.

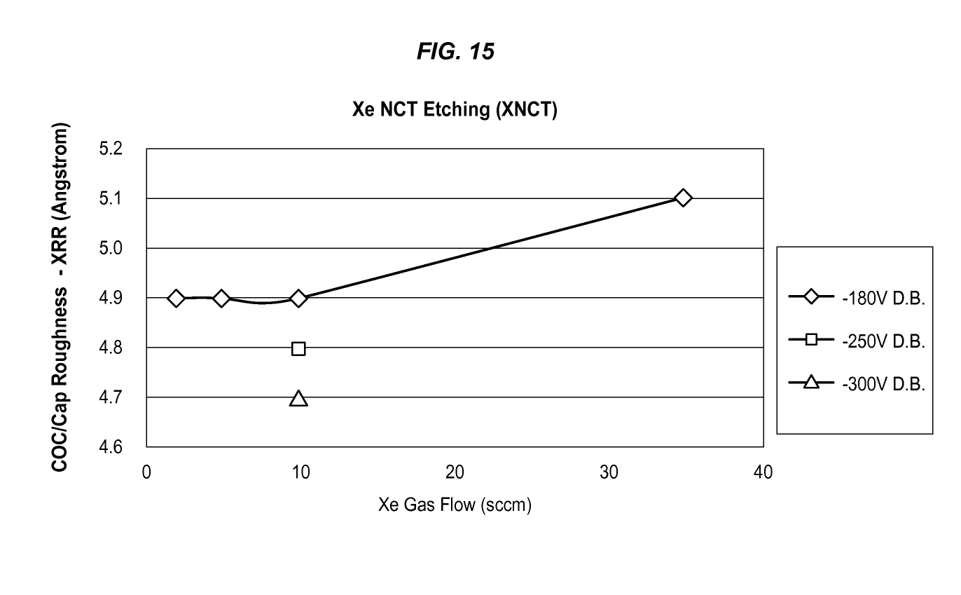

FIG. 15 is a graph illustrating variations in an interfacial roughness between a carbon overcoat and a cap layer using Xenon polishing at different bias voltages as determined during testing. The results plotted for FIG. 15 were obtained by XRR analysis using a NCT station and a bias of −180V, −250V, and −300V for Xenon polishing at a gas flow rate of 10 SCCM. The interfacial roughness at −180V was determined to be about 4.9 angstroms, while at −250V and −300V the interfacial roughness was reduced. In particular, the interfacial roughness at −250V was determined to be about 4.8 angstroms and the interfacial roughness at −300V was determined to be about 4.7 angstroms. This suggests that the interfacial roughness may be reduced using Xenon polishing as the magnitude of the bias voltage increases towards −300V.

As discussed, reducing the thickness of the carbon overcoat and/or the roughness of the top surface of the carbon overcoat is desirable for a number of reasons. One reason is that a thinner carbon overcoat reduces the magnetic spacing between read/write heads on the slider and the cap layer. This increases the signals sensed by the read head during a read process, and improves the magnetic field gradient applied to disk 1002 during a write process.

Another reason is that reducing the roughness of the carbon overcoat also improves the corrosion resistance of the disk. Typically, a rough carbon overcoat is made thicker to ensure that the corrosion resistance of the disk is sufficient. However, a thicker carbon overcoat increases the magnetic spacing between the read/write heads and the cap layer, which is undesirable. Using Xenon as a polishing ion in a plasma polishing process, the interfacial roughness between the carbon overcoat and the cap layer is reduced, which results in a smoother top surface for the carbon overcoat. This improves the corrosion resistance of the disk and consequentially, the carbon overcoat may be made thinner. Table 2 below illustrates the results of a Cobalt extraction test on magnetic media fabricated using Xenon polishing of the cap layer, which demonstrates that an acceptable corrosion resistance for the media can be achieved using a carbon overcoat thickness of about 20.4 Angstroms.

TABLE 2
corrosion resistance

| Carbon overcoat thickness | Cobalt extraction count |
|---|---|
| 23.1 angstroms | 0.9 nanograms |
| 21.3 angstroms | 1.9 nanograms |
| 20.4 angstroms | 4.8 nanograms |

A recording analysis was performed on media fabricated using Xenon polishing and Argon polishing in a NCT station. Xenon polishing at 10 SCCM was performed on a cap layer of a test media at a bias voltage of −180V prior to depositing a carbon overcoat. Argon polishing at 20 SCCM was performed on a cap layer of another test media at a bias voltage of −180V prior to depositing a carbon overcoat.

TABLE 3
recording analysis

| | | 2TS₀NRi | 2TSNRi | | TD |
|---|---|---|---|---|---|
| | Owi (dB) | (dB) | (dB) | FOM | (nm) |
| Xe polish | 34.9 | 23.9 | 11.1 | 1055 | 7.9 |
| Ar polish | 33.6 | 23.9 | 10.7 | 1035 | 7.8 |

Table 3 indicates that with the magnetic spacing reduction that results from Xenon polishing, areal density capacity can be increased by approximately 2%. The recording test was performed in a spin stand using SMR.

In the table, FOM is a recording parameter in the spin stand measurement which has been demonstrated to correlate with Areal Density Capacity (ADC). The 1.9% increase in FOM calculated from the data in the table indicates an approximately 2% increase in ADC. The SMR test was carried out with trimming from the inner diameter of the media. Owi is overwrite, 2TS₀NRi is the isolated signal-to-mid frequency noise ratio of the media, and 2TSNRi is the mid frequency signal-to-mid frequency noise ratio of the media. TD is a measurement of the clearance between the media and the read/write head.

The 0.4 dB of 2TSNRi increase of Xenon polished media is a direct result of the magnetic spacing reduction achieved from both clearance increase (TD increases from 7.8 nanometers for Argon polishing to 7.9 nanometers for Xenon polishing), and carbon overcoat thickness reduction. 2TS₀NRi is comparable between both Xenon polished and Argon polished media, which indicates that the intrinsic magnetic and recording performance of the media in is not degraded by using Xenon as a polishing ion.

Although specific embodiments were described herein, the scope is not limited to those specific embodiments. The scope is defined by the following claims and any equivalents thereof.

I claim:

1. A method of operating a carbon overcoat deposition station, the method comprising:
inserting a magnetic recording disk into the deposition station that includes a cap layer that is exchange coupled with a magnetic recording layer;
supplying a source of Xenon gas to the deposition station;
applying a negative bias voltage to the cap layer;
ionizing the Xenon gas in the deposition station to generate Xenon plasma; and
polishing the cap layer utilizing the Xenon plasma to a roughness of 5 angstroms or less.

2. The method of claim 1 further comprising:
terminating the source of Xenon gas to the deposition station;
supplying a source of carbon carrying gas to the deposition station; and
depositing a carbon overcoat on the polished cap layer.

3. The method of claim 2 wherein:
the magnetic recording disk is not removed from the deposition station between polishing the cap layer and depositing the carbon overcoat onto the polished cap layer.

4. The method of claim 2 wherein:
an interfacial roughness between the cap layer and the carbon overcoat is 5 angstroms or less.

5. The method of claim 2 wherein:
a thickness of the carbon overcoat is between 20.4 angstroms and 23.1 angstroms.

6. The method of claim 5 wherein:
the carbon overcoat has a Cobalt extraction count between 0.9 nanograms and 4.8 nanograms.

7. The method of claim 1 wherein:
the flow rate of Xenon is between 5 Standard Cubic Centimeter per Minute (SCCM) and 15 SCCM.

8. The method of claim 1 wherein:
the deposition station comprises a New Carbon Technology (NCT) deposition station.

9. The method of claim 8 wherein:
the negative bias voltage applied to the cap layer is between -180 Volts and -300 Volts.

10. A method of operating a carbon overcoat deposition station, the method comprising:
inserting a magnetic recording disk into the deposition station that includes a cap layer that is exchange coupled with a magnetic recording layer;
supplying a source of Xenon gas to the deposition station;
applying a negative bias voltage to the cap layer;
ionizing the Xenon gas in the deposition station to generate Xenon plasma;
polishing the cap layer utilizing the Xenon plasma;
terminating the source of Xenon gas to the deposition station;
supplying a source of carbon carrying gas to the deposition station; and
depositing a carbon overcoat on the polished cap layer.

11. The method of claim 10 wherein:
the cap layer is polished to a roughness of 5 angstroms or less.

12. The method of claim 10 wherein:
an interfacial roughness between the cap layer and the carbon overcoat is 5 angstroms or less.

13. The method of claim 10 wherein:
a thickness of the carbon overcoat is between 20.4 angstroms and 23.1 angstroms.

14. The method of claim 13 wherein:
the carbon overcoat has a Cobalt extraction count between 0.9 nanograms and 4.8 nanograms.

15. The method of claim 10 wherein:
the flow rate of Xenon is between 5 Standard Cubic Centimeter per Minute (SCCM) and 15 SCCM.

16. The method of claim 10 wherein:
the deposition station comprises a New Carbon Technology (NCT) deposition station.

17. The method of claim 16 wherein:
the negative bias voltage applied to the cap layer is between −180 Volts and −300 Volts.

18. A magnetic recording disk comprising:
a magnetic recording layer that is configured to store bit data for the magnetic recording disk;
a cap layer polished utilizing Xenon plasma to a roughness of 5 angstroms or less that is formed on and is exchanged coupled with the magnetic recording layer; and
a carbon overcoat formed on the cap layer.

19. The magnetic recording disk of claim 18 wherein:
the carbon overcoat has a thickness between 20.4 angstroms and 23.1 angstroms.

20. The magnetic recording disk of claim 19 wherein:
the carbon overcoat has a Cobalt extraction count between 0.9 nanograms and 4.8 nanograms.
